(19) United States
(12) Patent Application Publication
(10) Pub. No.: US 2014/0159086 A1
(43) Pub. Date: Jun. 12, 2014

(54) ACTIVE DEVICE ARRAY SUBSTRATE AND DISPLAY PANEL

(71) Applicant: HANNSTAR DISPLAY CORPORATION, New Taipei City (TW)

(72) Inventors: Chia-Hua YU, New Taipei City (TW); Sung-Chun LIN, Tainan City (TW); Chung-Lin CHANG, Kaohsiung City (TW); Chien-Ting CHAN, Tainan City (TW); Hsuan-Chen LIU, Kaohsiung City (TW)

(73) Assignee: HannStar Display Corporation, New Taipei City (TW)

(21) Appl. No.: 13/869,589

(22) Filed: Apr. 24, 2013

(30) Foreign Application Priority Data
Dec. 7, 2012 (CN) 201210523845.X

(51) Int. Cl. H01L 33/58

(52) U.S. Cl. CPC H01L 33/58
USPC 257/98

(57) ABSTRACT

An active device array substrate and a display panel are provided. The active device array substrate includes a substrate, a first conductor layer, a gate dielectric layer, a second conductor layer, an overcoat layer, a transparent electrode, a capacitive layer and pixel electrodes. The first conductor layer includes gate lines and light-shielding patterns. The gate dielectric layer covers the first conductor layer. The second conductor layer includes data lines and drain electrodes. Each of the data lines correspondingly overlaps one of the light-shielding patterns. The transparent electrode covers the overcoat layer. The pixel electrode is disposed on the capacitive layer and covers a portion of the shielding pattern. Each of the light-shielding patterns has a width greater than that of the overlapping data line. The gap between the edge of the light-shielding pattern and that of the overlapping data line is not greater than 2.5 microns.

### RELATED APPLICATIONS

This application claims priority to China Application Serial Number 201210523845.X, filed Dec. 7, 2012, which is herein incorporated by reference.

### BACKGROUND

1. Technical Field

The present disclosure relates to an active device array substrate,

2. Description of Related Art

A liquid crystal display panel mainly includes an active device array substrate, an opposite substrate and a liquid crystal layer. Twist angle of liquid crystal molecules in the liquid crystal layer can be controlled by a voltage difference between a pixel electrode and a common electrode, so as to adjust light transmittance of the liquid crystal display panel. However, the liquid crystal molecules over a data line are easily affected by the signal of the data line, such that an unexpected reverse domain of the liquid crystal molecules may occurs therein and lead to light leakage. Hence, it is required to dispose a light-shielding layer with a sufficient width on the opposite substrate. Nevertheless, the introduction of the light-shielding layer decreases an aperture ratio of the liquid crystal display panel.

In addition, in assembling the active device array substrate and the opposite substrate, if any offset thereof occurs, a portion of a sub-pixel area would be shielded by the light-shielding layer on the opposite substrate so as to significantly reduce the aperture ratio.

Therefore, there is a need for an active device array substrate having a high aperture ratio and able to avoid the light leakage.

### SUMMARY

One objective of the present disclosure provides an active device array substrate having a high aperture ratio and light-shielding patterns, and a display panel.

One aspect of the present disclosure provides an active device array substrate including a substrate, a first conductor layer, a gate dielectric layer, a second conductor layer, an overcoat layer, a transparent electrode, a capacitive layer and a plurality of pixel electrodes. The first conductor layer is disposed on the substrate and includes a plurality of gate lines and a plurality of light-shielding patterns. The gate dielectric layer covers the first conductor layer. The second conductor layer is disposed on the gate dielectric layer and includes a plurality of data lines and a plurality of drain electrodes, wherein each of the data lines correspondingly overlaps one of the light-shielding patterns. The data lines and the gate lines intersect with each other to define a plurality of sub-pixel areas of the substrate. The overcoat layer covers the second conductor layer and the sub-pixel areas of the substrate. The transparent electrode covers the overcoat layer, in which the transparent electrode has a common voltage potential. The capacitive layer covers the transparent electrode. The pixel electrodes are disposed on the capacitive layer and cover the sub-pixel areas of the substrate and a portion of the light-shielding patterns, wherein the pixel electrodes are respectively connected to the drain electrodes. Each of the light-shielding patterns has a width greater than the width of the overlapping data line, and a gap between the edge of each of the light-shielding patterns and the edge of the overlapping data line is less than or equal to 2.5 microns.

According to one embodiment of the present disclosure, one of the light-shielding patterns is electrically connected to the transparent electrode.

According to one embodiment of the present disclosure, the first conductor layer further includes at least one common electrode line parallel to an extending direction of the gate line, and one of the light-shielding patterns is connected to the common electrode line.

According to one embodiment of the present disclosure, the gap between the edge of each of the pixel electrodes and the adjacent edge of the data line is less than or equal to 2.5 microns.

According to one embodiment of the present disclosure, the transparent electrode further covers the first conductor layer.

According to one embodiment of the present disclosure, one of the light-shielding patterns is floated.

According to one embodiment of the present disclosure, a portion of each of the pixel electrodes correspondingly overlaps one of the light-shielding patterns.

According to one embodiment of the present disclosure, the portion of each of the pixel electrodes correspondingly overlapping the light-shielding pattern has a width less than or equal to 2.5 microns.

Another aspect of the present disclosure provides display panel including the above-mentioned active device array substrate, an opposite substrate and a display medium layer. The opposite substrate is parallel to the active device array substrate, and the opposite substrate includes a plurality of strip light-shielding layer respectively corresponding to the gate lines. The display medium layer is interposed between the active device array substrate and the opposite substrate.

According to one embodiment of the present disclosure, the opposite substrate further includes an opposite transparent electrode covering the strip light-shielding layers and electrically connected to the transparent electrode.

### BRIEF DESCRIPTION OF THE DRAWINGS

The disclosure may be more fully understood by reading the following detailed description of the embodiment, with reference made to the accompanying drawings as follows:

FIG. 1 is a top view of an active device array substrate according to one embodiment of the present disclosure;

FIG. 2 is a cross-sectional view of the active device array substrate taken along the line 2-2′ of FIG. 1;

FIG. 3 is a cross-sectional view of the active device array substrate taken along the line 3-3′ of FIG. 1; and

FIG. 4 is a top view of an active device array substrate according to another embodiment of the present disclosure.

### DETAILED DESCRIPTION

The present disclosure is described by the following specific embodiments. Those with ordinary skill in the arts can readily understand the other advantages and functions of the present invention after reading the disclosure of this specification. The present disclosure can also be implemented with different embodiments. Various details described in this specification can be modified based on different viewpoints and applications without departing from the scope of the present disclosure.

As used herein, the singular forms “a,” “an” and “the” include plural referents unless the context clearly dictates otherwise. Therefore, reference to, for example, a data sequence includes aspects having two or more such sequences, unless the context clearly indicates otherwise.

Reference will now be made in detail to the embodiments of the present disclosure, examples of which are illustrated in the accompanying drawings. Wherever possible, the same reference numbers are used in the drawings and the description to refer to the same or like parts.

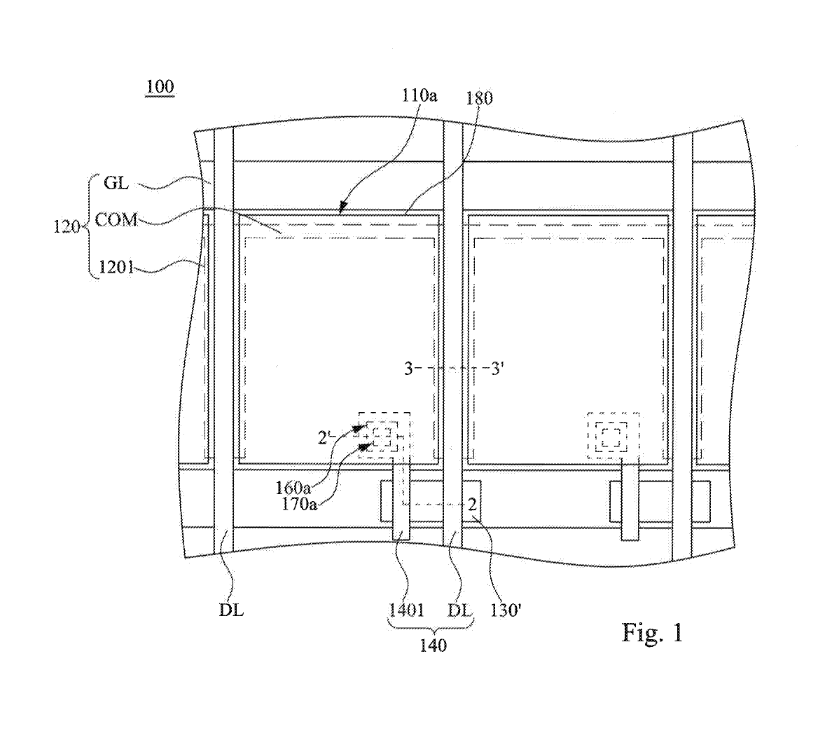

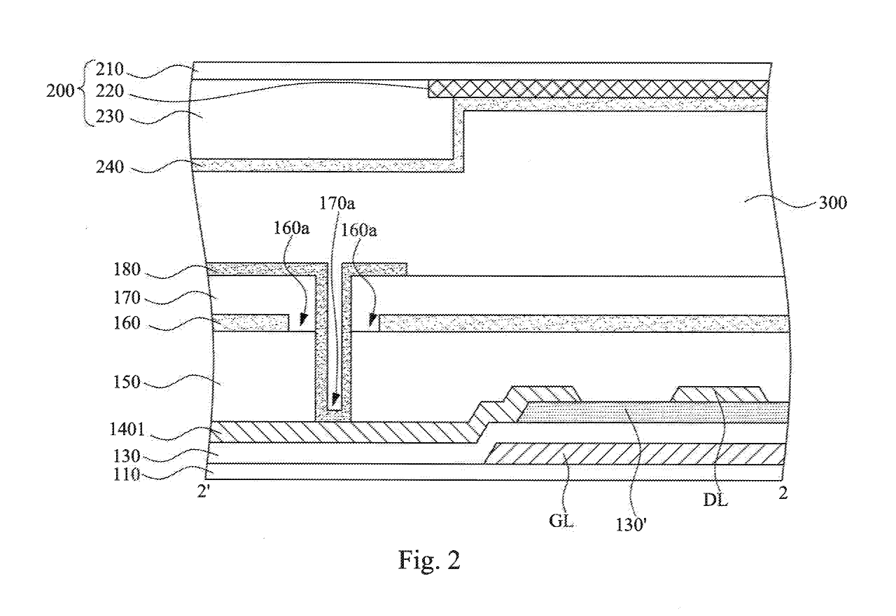

FIG. 1 is a top view of an active device array substrate 100 according to one embodiment of the present disclosure. FIG. 2 is a cross-sectional view of the active device array substrate 100 taken along the line 2-2′ of FIG. 1.

Referring to FIG. 1 and FIG. 2, the active device array substrate 100 includes a substrate 110, a first conductor layer 120, a gate dielectric layer 130, a second conductor layer 140, an overcoat layer 150, a transparent electrode 160, a capacitive layer 170 and pixel electrodes 180.

The substrate 110 should have high light transmittance and sufficient mechanical strength, which may be made of glass, quartz, transparent polymeric materials or other suitable materials.

The first conductor layer 120 is disposed on the substrate 110 and includes gate lines GL parallel to each other and light-shielding patterns 1201, as shown in FIG. 1. In the embodiment, a portion of the gate line GL is acted as a gate electrode. The light-shielding patterns 1201 are disposed on predetermined areas of data lines to act as a light-shielding layer, such that there is no need for further disposing light-shielding layers corresponding to the data lines on an opposite substrate. The size relationship between the light-shielding pattern 1201 and the data line will be described in detail below.

In the embodiment, the first conductor layer 120 further includes at least one common electrode line COM parallel to an extending direction of the gate line GL, and one of the light-shielding patterns 1201 is connected to the common electrode line COM. As shown in FIG. 1, the common electrode line COM and the light-shielding patterns 1201 are formed in a continuous pattern. However, the embodiment of the light-shielding pattern 1201 connected to the common electrode line COM is not limited thereto.

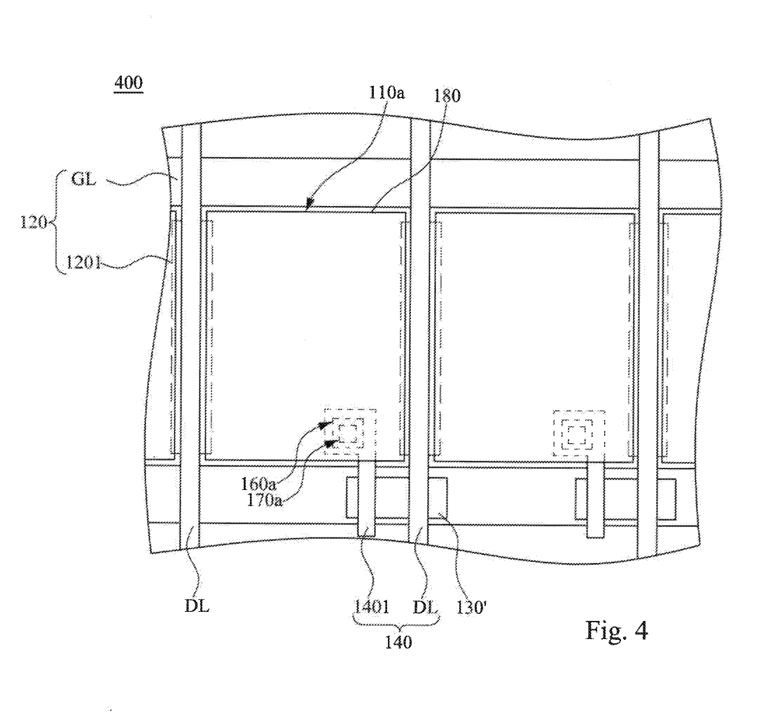

In another embodiment, light-shielding patterns 1201 of an active device array substrate 400 are floated, as shown in FIG. 4. In other words, the light-shielding patterns 1201 are not electrically connected to other thin film layers and in an electrically floating state.

The gate dielectric layer 130 covers the first conductor layer 120, as shown in FIG. 2. The gate dielectric layer 130 may be made of silicon nitride or silicon oxide. The gate dielectric layer 130 may blanket cover the first conductor layer 120.

An active layer 130′ is disposed on the gate dielectric layer 130, as shown in FIG. 1. The active layer 130′ may be made of a material including amorphous silicon, polycrystalline silicon, oxide semiconductors or a combination thereof. The shape and the position of the active layer 130′ in practical applications are not limited to the embodiment shown in FIG. 1.

The second conductor layer 140 is disposed on the gate dielectric layer 130 and includes data lines DL parallel to each other and drain electrodes 1401, as shown in FIG. 1. In the embodiment, a portion of the data line DL is acted as a source electrode. The first conductor layer 120 and the second conductor layer 140 may be made of molybdenum (Mo), chromium (Cr), aluminum (Al), neodymium (Nd), titanium (Ti) or a combination thereof. The material of the second conductor layer 140 may be the same as or different from that of the first conductor layer 120.

The data lines DL and the gate lines GL are intersected to define sub-pixel areas 110a of the substrate 110, as shown in FIG. 1. Moreover, a thin film transistor is constituted by the gate electrode (i.e., a portion of the gate line GL), the active layer 130′, the source electrode (i.e., a portion of the data line DL) and the drain electrode 1401. Certainly, a person skilled in the art understands that the circuit layout may be appropriately changed, and not limited to the embodiment shown in FIG. 1.

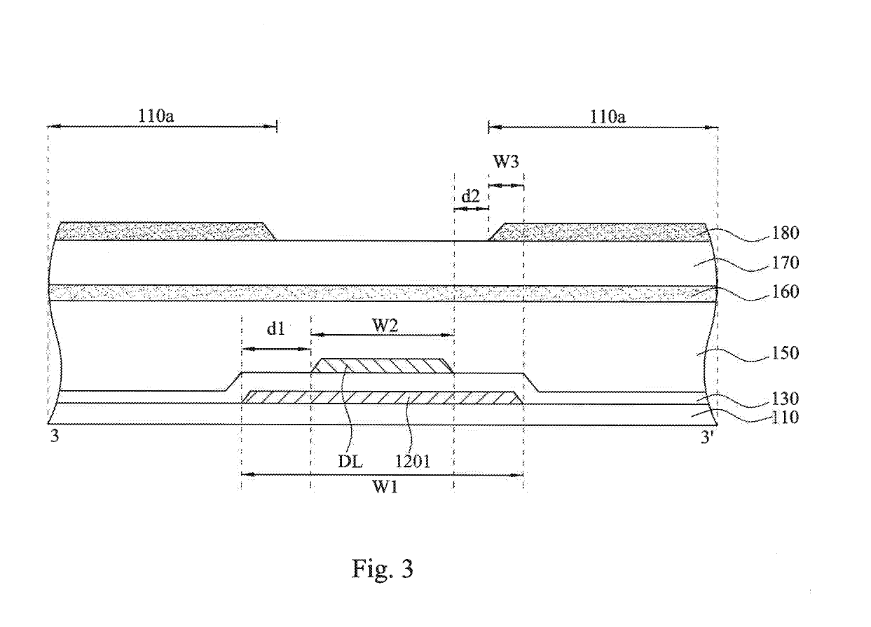

It is worth mentioning that each of the data lines DL overlaps one of the light-shielding patterns 1201, and each of the light-shielding patterns 1201 has a width W1 greater than the width W2 of the overlapping data line DL, as shown in FIG. 3. FIG. 3 is a cross-sectional view of the active device array substrate taken along the line 3-3′ of FIG. 1. That is to say, the projection of the data line DL to the substrate 110 should be included in that of the light-shielding patterns 1201 to the substrate 110. Because the light-shielding patterns 1201 of the present disclosure are able to effectively shield the light from a backlight module and avoid light leakage, there is no need for further disposing light-shielding layers corresponding to the data lines DL on the opposite substrate so as to enable the display panel to have a high aperture ratio. The reason will be described in detail hereinafter.

The overcoat layer 150 covers the second conductor layer 140 and the sub-pixel areas 110a of the substrate 110, as shown in FIG. 2 and FIG. 3. The overcoat layer 150 may further cover the first conductor layer 120 to protect the thin film transistor and lines beneath the overcoat layer 150. The overcoat layer 150 may be made of organic insulating materials or inorganic insulating materials.

The transparent electrode 160 covers the overcoat layer 150 and has a common voltage potential, as shown in FIG. 2 and FIG. 3. In other words, the common voltage potential is applied to the transparent electrode 160 so as to make it have the common voltage potential. The transparent electrode 160 covers the second conductor layer 140 to prevent the signal from following pixel electrodes 180 from being interfered with the signal from the data lines DL.

The capacitive layer 170 covers the transparent electrode 160, as shown in FIG. 2 and FIG. 3. The pixel electrodes 180 are disposed on the capacitive layer 170 and cover the sub-pixel areas 110a of the substrate 110 and a portion of the light-shielding patterns 1201, as shown in FIG. 1 and FIG. 3. The pixel electrode 180 is connected to the drain electrode 1401 through a contact hole 170a of the capacitive layer 170, as shown in FIG. 2. The capacitive layer 170 is interposed between the transparent electrode 160 and the pixel electrode 180 to isolate the transparent electrode 160 from the pixel electrode 180. Further, as shown in FIG. 2, the transparent electrode 160 has an opening 160a, and the pixel electrode 180 in the contact hole 170a is isolated from the transparent electrode 160 by the capacitive layer 170.

In addition, a transparent capacitor with a large area composed of the transparent electrode 160, the capacitive layer 170 and the pixel electrode 180 is formed, such that the active device array substrate of the present disclosure has a higher aperture ratio compared to a general active device array substrate having a metal capacitor. The transparent electrode 160 and the pixel electrode 180 may be made of indium tin oxide (ITO), indium zinc oxide (IZO) or other suitable transparent conductive materials. The material of the pixel electrode 180 may be the same as or different from that of the transparent electrode 160.

In general, a capacitive coupling effect between the data line and the pixel electrode is generated to make the liquid crystal form a reverse domain, and thus lead to light leakage. In order to avoid the occurrence of the phenomenon, there is a need for a sufficiently wide gap between the data line and the pixel electrode to prevent the generation of the capacitive coupling effect; that is, the area of the pixel electrode becomes small. The aperture ratio of the sub-pixel area becomes low due to the small area of the pixel electrode. If the gap becomes wider, the width of the light-shielding layer should be wider for shielding light. As such, the aperture ratio of the display panel is further reduced.

However, in the embodiment of the present disclosure, the transparent electrode 160 covers the overcoat layer 150 and the data lines DL of the second conductor layer 140 therebeneath so as to effectively shield the capacitive coupling effect between the data lines DL and the pixel electrodes 180. Therefore, the gap between the data line DL and the pixel electrode 180 of the present disclosure is less than that in the art. In one embodiment, the gap d2 between the edge of each of the pixel electrodes 180 and the edge of the adjacent data line DL is less than or equal to 2.5 microns, as shown in FIG. 3.

Because of the small gap d2 of the embodiment of the present disclosure, the width W1 of the light-shielding pattern 1201 only needs to be slightly larger than the width W2 of the data line DL. Therefore, in one embodiment, a gap d1 between the edge of the light-shielding pattern 1201 and the edge of the overlapping data line DL is less than or equal to 2.5 microns, preferably less than or equal to 2.0 microns, as shown in FIG. 3. As such, the only factor needed to be considered is the overlapping tolerance of the light-shielding pattern 1201 and the data line DL during a photolithographic process.

In one embodiment, a portion of each of the pixel electrodes 180 overlaps one of the light-shielding patterns 1201. As shown in FIG. 1, each of the two opposite sides of the pixel electrode 180 overlaps a portion of the light-shielding pattern 1201. In one embodiment, a portion of each of the pixel electrodes 180 overlapping the light-shielding pattern 1201 has a width W3 less than or equal to 2.5 microns, as shown in FIG. 3. In the embodiment, the light-shielding patterns 1201 are able to effectively shield light, such that there is no need for further disposing light-shielding layers corresponding to the data lines DL on the opposite substrate.

In one embodiment, the transparent electrode 160 covers the second conductor layer 140, the sub-pixel areas 110a of the substrate 110 and the first conductor layer 120, as shown in FIG. 2. In one embodiment, the transparent electrode 160 blanket covers the overcoat layer 150 so as to completely shield the capacitive coupling effect between the data lines DL, the gate lines GL and the above-mentioned thin film transistors, and the pixel electrodes 180. That is, the signal from the data lines DL, the gate lines GL and the above-mentioned thin film transistors can be shielded beneath the transparent electrode 160 and thus does not interfere with the signal of the pixel electrodes 180.

In one embodiment, one of the light-shielding patterns 1201 is electrically connected to the transparent electrode 160. That is, the light-shielding pattern 1201 and the transparent electrode 160 both have the common voltage potential. Therefore, the electric potentials above and beneath the data line DL are the same so as to enhance the shielding effect of the transparent electrode 160.

Another aspect of the present disclosure provides a display panel including the above-mentioned active device array substrate 100, an opposite substrate 200 and a display medium layer 300, as shown in FIG. 2. The embodiments of each of the elements of the above-mentioned active device array substrate 100 may be referenced and not discussed here.

The opposite substrate 200 is parallel to the active device array substrate 100. In the embodiment, the opposite substrate 200 includes an opposite base plate 210, strip light-shielding layers 220 and color filters 230. The strip light-shielding layers 220 are respectively corresponding to the gate lines GL. Since the light-shielding patterns 1201 of the active device array substrate 100 can effectively shield the light from the backlight module, there is no need for further disposing light-shielding layers corresponding to the data lines DL on the opposite substrate 200. Because of this, when the opposite substrate 200 is offset from the active device array substrate 100 in a direction perpendicular to the extending direction of the data line DL (i.e., the direction parallel to the extending direction of the gate line GL) during assembling, it does not seriously affect the aperture ratio of the display panel.

In one embodiment, the opposite substrate 200 further includes an opposite transparent electrode 240 covering the strip light-shielding layers 220 and electrically connected to the transparent electrode 160. Concerning a twisted nematic liquid crystal display (TN-LCD), the voltage between the opposite transparent electrode 240 and the pixel electrode 180 can be utilized to control the twist angle of the liquid crystal molecules so as to control the degree of light penetration.

The display medium layer 300 is interposed between the active device array substrate 100 and the opposite substrate 200. The display medium layer 300 may be made of liquid crystal, electrowetting materials, self-luminous materials or other suitable materials.

From the above, the transparent electrode is utilized to shield the coupling capacitive effect between the data lines therebeneath and the pixel electrodes thereabove so as to prevent the signal from the pixel electrodes from being interfered with the signal from the data lines. Therefore, the edge of the pixel electrode can be very close to the data line, and the gap between the edge of the light-shielding pattern and the edge of the overlapping data line can be very small, less than or equal to 2.5 microns. As such, the active device array substrate of the embodiments of the present disclosure has an ultrahigh aperture ratio and the effect of preventing the light leakage. In addition, it is possible not to further dispose light-shielding layers corresponding to the data lines on the opposite substrate, so as to further increase the aperture ratio of the display panel.

Although the present disclosure has been described in considerable detail with reference to certain embodiments thereof, other embodiments are possible. Therefore, the spirit and scope of the appended claims should not be limited to the description of the embodiments contained herein.

It will be apparent to those ordinarily skilled in the art that various modifications and variations may be made to the structure of the present disclosure without departing from the scope or spirit of the disclosure. In view of the foregoing, it is intended that the present disclosure cover modifications and variations thereof provided they fall within the scope of the following claims.

What is claimed is:

1. An active device array substrate, comprising:
a substrate;
a first conductor layer disposed on the substrate and comprising a plurality of gate lines and a plurality of light-shielding patterns;
a gate dielectric layer covering the first conductor layer;
a second conductor layer disposed on the gate dielectric layer and comprising a plurality of data lines and a plurality of drain electrodes, wherein each of the data lines correspondingly overlaps one of the light-shielding patterns, and the data lines and the gate lines intersect with each other to define a plurality of sub-pixel areas of the substrate;
an overcoat layer covering the second conductor layer and the sub-pixel areas of the substrate;
is a transparent electrode covering the overcoat layer, wherein the transparent electrode has a common voltage potential;
a capacitive layer covering the transparent electrode; and
a plurality of pixel electrodes disposed on the capacitive layer and covering the sub-pixel areas of the substrate and a portion of the light-shielding patterns, wherein the pixel electrodes are respectively connected to the drain electrodes,
wherein each of the light-shielding patterns has a width greater than the width of the overlapping data line, and a gap between the edge of each of the light-shielding patterns and the edge of the overlapping data line is less than or equal to 2.5 microns.

2. The active device array substrate of claim 1, wherein one of the light-shielding patterns is electrically connected to the transparent electrode.

3. The active device array substrate of claim 1, wherein the first conductor layer further comprises at least one common electrode line parallel to an extending direction of the gate line, and one of the light-shielding patterns is connected to the common electrode line.

4. The active device array substrate of claim 1, wherein the gap between the edge of each of the pixel electrodes and the adjacent edge of the data line is less than or equal to 2.5 microns.

5. The active device array substrate of claim 1, wherein the transparent electrode further covers the first conductor layer.

6. The active device array substrate of claim 1, wherein one of the light-shielding patterns is floated.

7. The active device array substrate of claim 1, wherein a portion of each of the pixel electrodes correspondingly overlaps one of the light-shielding patterns.

8. The active device array substrate of claim 7, wherein the portion of each of the pixel electrodes correspondingly overlapping the light-shielding pattern has a width less than or equal to 2.5 microns.

9. A display panel, comprising:
an active device array substrate according to claim 1;
an opposite substrate parallel to the active device array substrate, and comprising a plurality of strip light-shielding layer respectively corresponding to the gate lines; and
a display medium layer interposed between the active device array substrate and the opposite substrate.

10. The display panel of claim 9, wherein the opposite substrate further comprises an opposite transparent electrode covering the strip light-shielding layers and electrically connected to the transparent electrode.
